(19) United States
(12) Patent Application Publication
(10) Pub. No.: US 2014/0139245 A1
(43) Pub. Date: May 22, 2014

(54) SEMICONDUCTOR DEVICE DRIVING CIRCUIT AND METHOD OF TESTING THE SAME

(71) Applicant: MITSUBISHI ELECTRIC CORPORATION, Tokyo (JP)

(72) Inventor: Daisuke HIRATA, Tokyo (JP)

(73) Assignee: MITSUBISHI ELECTRIC CORPORATION, Tokyo (JP)

(21) Appl. No.: 13/966,033

(22) Filed: Aug. 13, 2013

(30) Foreign Application Priority Data
Nov. 16, 2012 (JP) 2012-251780

(51) Int. Cl. G01R 31/40

(52) U.S. Cl. CPC G01R 31/40
USPC 324/750.01

(57) ABSTRACT

A semiconductor device driving circuit includes: a driving circuit that drives a semiconductor device; an input circuit that gives a control signal to the driving circuit; a driving power source that drives output stages of the driving circuit; and a control power source provided independently of the driving power source, and which drives the input circuit. Only the driving voltage of the driving power source is reduced during a test and the current capability of the driving circuit is adjusted based on the current capabilities of the output stages in a pentode region.

### FIELD OF THE INVENTION

The present invention relates to a semiconductor device driving circuit that drives a semiconductor device provided to drive a load arranged for example in a high-voltage circuit, and a method of testing the semiconductor device driving circuit.

### BACKGROUND ART

A conventional semiconductor device driving circuit includes a driving circuit having an output stage of an MOSFET (metal oxide semiconductor field effect transistor), an input circuit that shapes the waveform of an input signal, and a driving power source that drives the driving circuit and the input circuit (see for example Japanese Patent Application Laid-Open Nos. 2001-016082 and 7-122985 (1995)).

In the conventional semiconductor device driving circuit, testing and evaluating the output current capability (capability to source or sink a current, which will also be called current capability) of the driving circuit encounters the following: a power source voltage is too high during normal operation, and a relatively high current value should be measured so the measurement consumes too much power. This makes it impossible to evaluate the current capability of the driving current directly. The driving circuit and the input circuit are driven by the common driving power source, so that the current capability has been evaluated based on the on-resistance of the MOSFET output stage measured in a triode region. However, measured values obtained by this method of measurement vary widely, so that the current capability cannot be measured accurately. Further, the MOSFET output stage cannot achieve desirable current capability in some cases due to manufacturing variations. In response, there has been a technique conventionally employed such as laser trimming that makes adjustment to obtain desirable characteristics (a design value of the output current capability of the driving circuit) by cutting a wiring pattern and the like with a laser based on a measured result about each characteristic of a finished semiconductor element. Meanwhile, the aforementioned method of evaluating the current capability of the MOSFET output stage cannot measure current capability accurately, as described above. Thus, even if this adjustment technique is employed in the adjustment of the current capability of the MOSFET output stage, it is still hard to make adjustment accurately such that the current capability becomes desirable characteristics.

### SUMMARY OF THE INVENTION

It is an object of the present invention to provide a semiconductor device driving circuit and a method of testing the same capable of making adjustment such that the current capability of a driving circuit becomes desirable characteristics.

The semiconductor device driving circuit of the present invention includes: a driving circuit that drives a semiconductor device; an input circuit that gives a control signal to the driving circuit; a driving power source that drives MOSFET output stages of the driving circuit; and a control power source provided independently of the driving power source, and which drives the input circuit. Only the driving voltage of the driving power source is reduced during a test and the current capability of the driving circuit is adjusted based on the current capabilities of the MOSFET output stages in a pentode region.

According to the present invention, the semiconductor device driving circuit includes: a driving circuit that drives a semiconductor device; an input circuit that gives a control signal to the driving circuit; a driving power source that drives MOSFET output stages of the driving circuit; and a control power source provided independently of the driving power source, and which drives the input circuit. Only the driving voltage of the driving power source is reduced during a test and the current capability of the driving circuit is adjusted based on the current capabilities of the MOSFET output stages in a pentode region. This allows adjustment such that the current capability of the driving circuit becomes desirable characteristics.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows an example of the structure of a semiconductor device driving circuit according to a first preferred embodiment of the present invention;

FIG. 2 shows an example of the structure of a semiconductor device driving circuit according to a second preferred embodiment of the present invention;

FIG. 3 shows an example of the structure of a semiconductor device driving circuit according to a third preferred embodiment of the present invention;

FIG. 4 shows an example of the structure of a semiconductor device driving circuit according to a fourth preferred embodiment of the present invention;

FIG. 5 shows an example of the structure of a semiconductor device driving circuit according to a fifth preferred embodiment of the present invention; and

FIG. 6 shows an example of the structure of a semiconductor device driving circuit according to a prerequisite technique.

### EMBODIMENT FOR CARRYING OUT THE INVENTION

Preferred embodiments of the present invention are described below based on the drawings.

### <Prerequisite Technique>

A technique prerequisite to the present invention is described first.

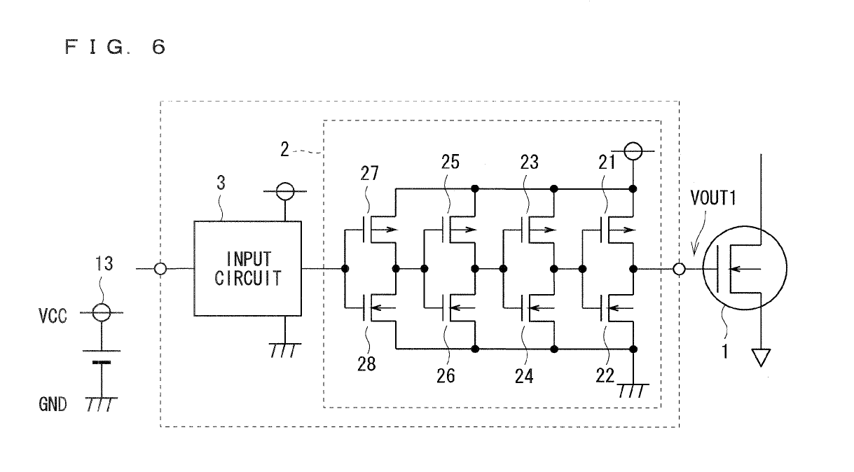

FIG. 6 shows an example of the structure of a semiconductor device driving circuit according to the prerequisite technique.

As shown in FIG. 6, the semiconductor device driving circuit of the prerequisite technique includes a driving circuit 2 that drives a semiconductor device 1, an input circuit 3 that shapes the waveform of an input signal and then inputs the resultant signal to the driving circuit 2, and a driving power source 13 that drives the driving circuit 2 and the input circuit 3.

The semiconductor device 1 is provided to drive a load arranged for example in a high-voltage circuit, and is composed of an N-channel MOSFET. The semiconductor device 1 can also be composed of a P-channel MOSFET.

The driving circuit 2 has output stages 21 to 28. A combination of the output stages 21 and 22, that of the output stages 23 and 24, that of the output stages 25 and 26, and that of the output stages 27 and 28 each form a CMOSFET (complementary MOSFET), and this CMOSFET functions as an inverter. The inverter is composed of an arbitrary number of stages.

In the semiconductor device driving circuit of the prerequisite technique, regarding testing and evaluating the current capability of the driving circuit 2, the current capability of the driving circuit 2 cannot be evaluated directly during high-voltage operation of the driving circuit 2 that is normal operation thereof Hence, the current capability of the driving circuit 2 is evaluated based on the on-resistances of the output stages 21 to 28 measured in a triode region. This method of evaluation measures the on-resistances in a triode region. Thus, even if adjustment is made based on the evaluation, the current capability of the driving circuit 2 cannot become desirable characteristics (a design value of the current capability of the driving circuit 2).

The present invention has been made to solve this problem, and is described in detail below.

### First Preferred Embodiment

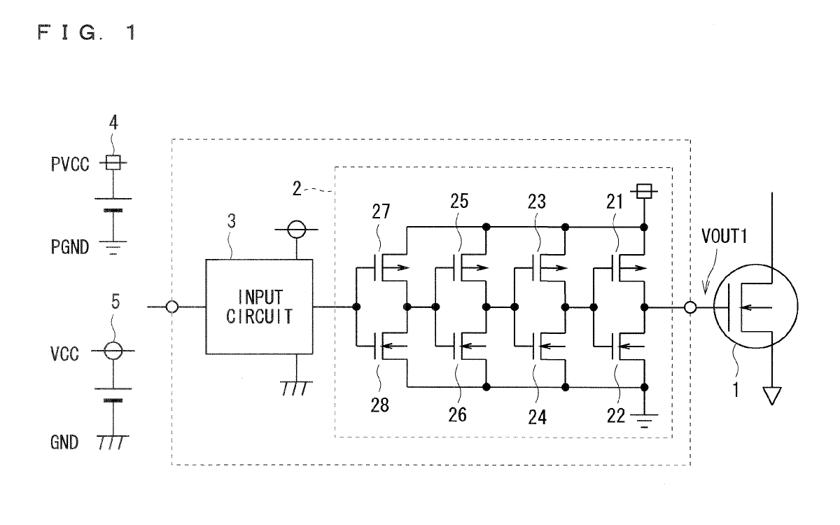

FIG. 1 shows an example of the structure of a semiconductor device driving circuit according to a first preferred embodiment of the present invention.

As shown in FIG. 1, the semiconductor device driving circuit of the first preferred embodiment includes a driving circuit 2 that drives a semiconductor device 1, an input circuit 3 that shapes the waveform of an input signal and inputs the resultant signal as a control signal to the driving circuit 2, a driving power source 4 that drives output stages 21 to 28 (MOSFET output stages) of the driving circuit 2, and a control power source 5 provided independently of the driving power source 4 and which drives the input circuit 3.

A method of adjusting the current capability of the driving circuit 2 (method of testing a semiconductor device driving circuit) is described next.

First, to establish a standard for a semiconductor device driving circuit to be manufactured, correlation is examined in advance between current capability determined when the driving voltage of the driving power source 4 is low and that determined when the driving voltage thereof is a general driving voltage.

Next, during test of each manufactured semiconductor device driving circuit, current capability is measured when the driving voltage of the driving power source 4 is low. At this time, only the driving voltage of the driving power source 4 is reduced in the semiconductor device driving circuit. Thus, Vds (drain-to-source voltage) and Vgs (gate-to-source-voltage) are reduced by the same amount in each of the output stages 21 to 28, making it possible to reduce the current capability of each of the output stages 21 to 28 while maintaining the output stages 21 and 28 in a pentode region.

Next, adjustment is made by trimming such that the current capability measured under the low driving voltage becomes desirable characteristics with respect to the previously examined current capability determined under the low driving voltage. At this time, current capability determined under the general driving voltage can be adjusted by taking the previously examined correlation into consideration. To be specific, based on the current capability measured under the low driving voltage, the current capability determined under the general driving voltage is adjusted by taking the previously examined correlation into consideration, thereby allowing adjustment of the current capability of the driving circuit 2. A known technique such as laser trimming is applicable as an exemplary way of the trimming. More specifically, a fuse made of an aluminum line of a wiring pattern is cut, for example. This places the aluminum line in an open condition to allow switching between signals. To be specific, the output stages 21 and 22 are composed of a plurality of MOSFETs connected in parallel. To adjust the amount of current to flow into the output stages, it is determined if each of the MOSFETs is to operate (to receive an input signal and to be turned on or off), or is not to operate (always off independently of an input signal) by opening or shorting the aforementioned fuse. Then, the number of the MOSFETs to be connected in parallel in the output stages 21 and 22 is determined, thereby adjusting a current value.

As described above, in the first preferred embodiment, only the driving voltage of the driving power source 4 is reduced during the test, and the current capabilities of the output stages 21 and 22 of the driving circuit 2 are adjusted based on the current capabilities of the output stages 21 and 28 in a pentode region. This allows adjustment such that the current capability of the driving circuit 2 becomes desirable characteristics.

### Second Preferred Embodiment

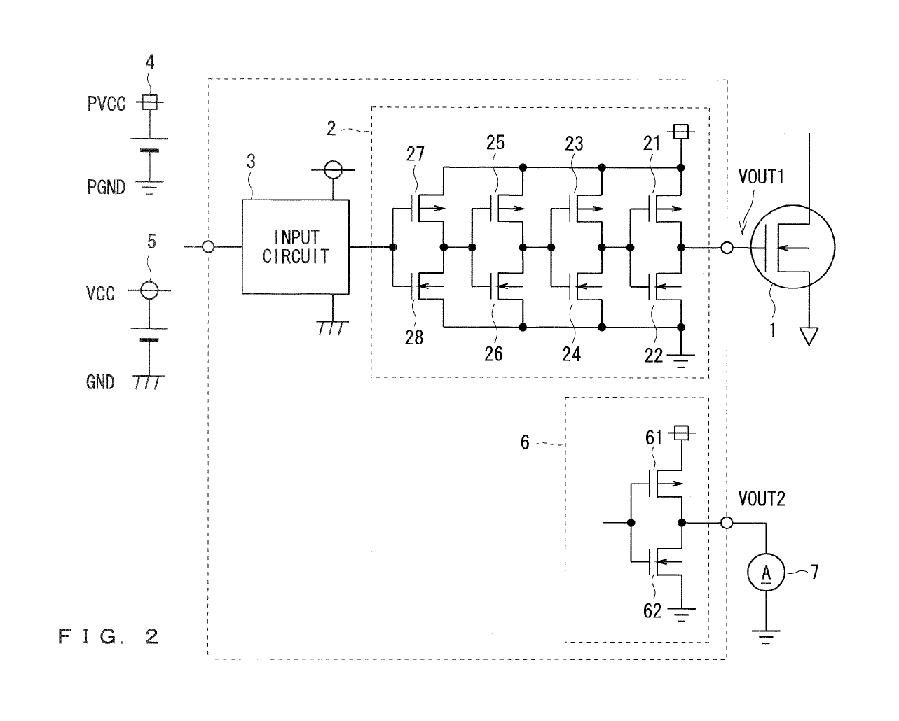

FIG. 2 shows an example of the structure of a semiconductor device driving circuit according to a second preferred embodiment of the present invention.

As shown in FIG. 2, the semiconductor device driving circuit of the second preferred embodiment includes output stages 61 and 62 (test MOSFET output stages) corresponding to the output stages 21 and 22 (MOSFET output stages) respectively of the driving circuit 2, and a test circuit 6 driven by the driving power source 4.

In a layout, the output stages 61 and 62 of the test circuit 6 are paired with the output stages 21 and 22 of the driving circuit 2 respectively. The current capabilities of the output stages 61 and 62 are 1/n of the current capabilities of the output stages 21 and 22 respectively. A DC ammeter 7 to measure a current output from the test circuit 6 is connected to the test circuit 6. The structure of the second preferred embodiment is the same in other respects as that of the first preferred embodiment, so that it will not be described here. Paring between output stages mentioned here means arranging the output stages in relation to each other (arranging the output stages in proximity to each other, for example) such that they receive the same process error.

A method of adjusting the current capability of the driving circuit 2 (method of testing a semiconductor device driving circuit) is described next. Referring to FIG. 2, the driving circuit 2 and the input circuit 3 perform the same operations as those of the first preferred embodiment. Control signals to be input to the gates of the output stages 61 and 62 of the test circuit 6 correspond to control signals to be input to the gates of the output stages 21 and 22 of the driving circuit 2 respectively. To be specific, the output stages 61 and 62 are driven by voltages common to those for the output stages 21 and 22 respectively.

First, the current capabilities of the output stages 61 and 62 are measured with the DC ammeter 7.

Next, differences x[%] between the measured current capabilities of the output stages 61 and 62 and desirable characteristics are checked.

Then, the current capabilities of the output stages 21 and 22 are adjusted by trimming the aforementioned difference x[%]. To be specific, the current capabilities of the output stages 21 and 22 are adjusted based on the measured current capabilities of the output stages 61 and 62 and design values of the current capabilities of the output stages 61 and 62. Current capability output from the driving circuit 2 is adjusted by adjusting the current capabilities of the output stages 21 and 22.

As described above, in the second preferred embodiment, the current capabilities of the output stages 21 and 22 of the driving circuit 2 are adjusted based on the current capabilities of the output stages 61 and 62 of the test circuit 6. This allows adjustment such that the current capability of the driving circuit 2 becomes desirable characteristics.

In the second preferred embodiment, a common power source is used for the test circuit 6 and the driving circuit 2. Meanwhile, respective power sources may be prepared for the test circuit 6 and the driving circuit 2, and only the test circuit 6 may be driven during the test.

### Third Preferred Embodiment

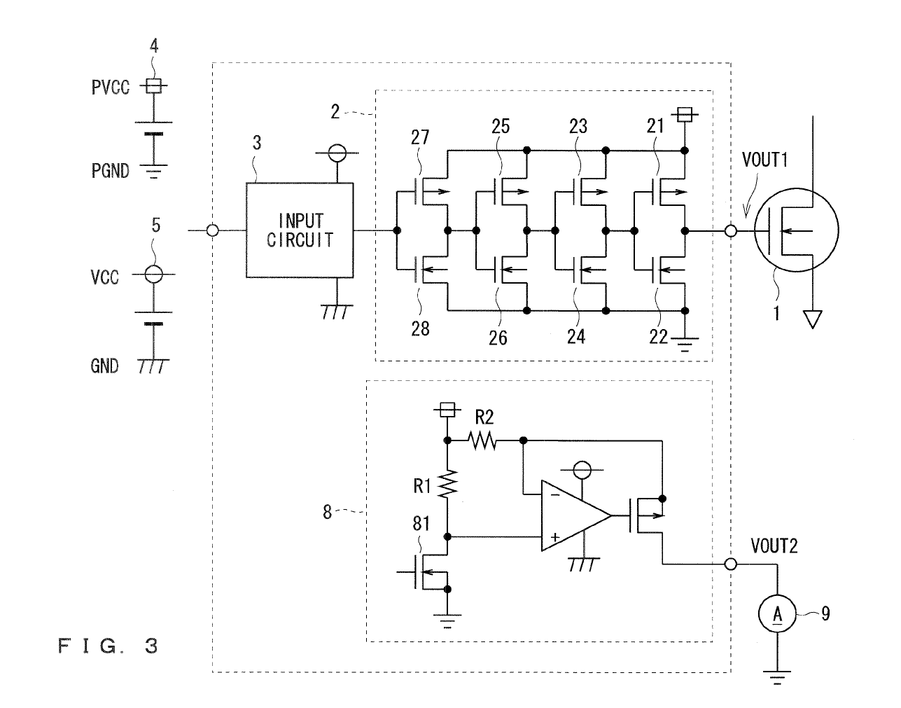

FIG. 3 shows an example of the structure of a semiconductor device driving circuit according to a third preferred embodiment of the present invention.

As shown in FIG. 3, the semiconductor device driving circuit of the third preferred embodiment includes an output stage 81 (first transistor) corresponding to the N-channel output stage 22 (N-channel MOSFET output stage) of the output stages 21 to 28 of the driving circuit 2, and a current detecting circuit 8 (first current detecting circuit) driven by the driving power source 4.

In a layout, the output stage 81 of the current detecting circuit 8 is paired with the output stage 22 of the driving circuit 2. The current capability (sinking capability) of the output stage 81 is 1/n of the current capability (sinking capability) of the output stage 22. In a layout, resistors R1 and R2 of the current detecting circuit 8 are paired with each other. A DC ammeter 9 to measure a current output from the current detecting circuit 8 is connected to the current detecting circuit 8. The structure of the third preferred embodiment is the same in other respects as that of the first preferred embodiment, so that it will not be described here.

A method of adjusting the current capability of the driving circuit 2 (method of testing a semiconductor device driving circuit) is described next. Referring to FIG. 3, the driving circuit 2 and the input circuit 3 perform the same operations as those of the first preferred embodiment. A control signal to be input to the gate of the output stage 81 of the current detecting circuit 8 corresponds to a control signal to be input to the gate of the output stage 22 of the driving circuit 2. To be specific, the output stage 81 is driven by a voltage common to that for the output stage 22.

First, a short-circuit current is caused to flow in the output stage 81 of the current detecting circuit 8. The short-circuit current is diverted through the resistors R1 and R2, and current capability output from the current detecting circuit 8 is measured with the DC ammeter 9.

Next, a difference x[%] between the measured current capability of the output stage 81 and desirable characteristics is checked.

Then, the current capability of the output stage 22 is adjusted by trimming the aforementioned difference x[%]. To be specific, the current capability of the output stage 22 is adjusted based on the measured current capability of the output stage 81 and a design value of the current capability of the output stage 81. Current capability output from the driving circuit 2 is adjusted by adjusting the current capability of the output stage 22.

As described above, in the third preferred embodiment, the current capability of the driving circuit 2 is adjusted based on the current capability of the output stage 81 of the current detecting circuit 8. This allows adjustment such that the current capability of the driving circuit 2 becomes desirable characteristics.

In the third preferred embodiment, a common power source is used for the current detecting circuit 8 and the driving circuit 2. Meanwhile, respective power sources may be prepared for the current detecting circuit 8 and the driving circuit 2, and only the current detecting circuit 8 may be driven during the test.

### Fourth Preferred Embodiment

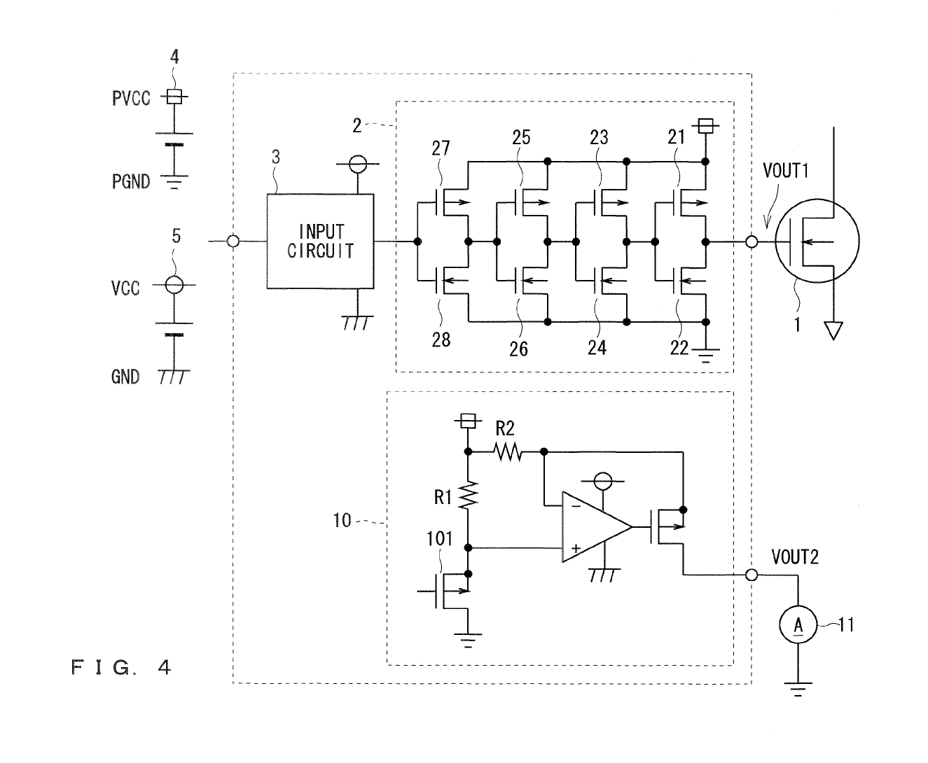

FIG. 4 shows an example of the structure of a semiconductor device driving circuit according to a fourth preferred embodiment of the present invention.

As shown in FIG. 4, the semiconductor device driving circuit of the fourth preferred embodiment includes an output stage 101 (second transistor) corresponding to the P-channel output stage 21 (P-channel MOSFET output stage) of the output stages 21 to 28 of the driving circuit 2, and a current detecting circuit 10 (second current detecting circuit) driven by the driving power source 4.

In a layout, the output stage 101 of the current detecting circuit 10 is paired with the output stage 21 of the driving circuit 2. The current capability (sourcing capability) of the output stage 101 is 1/n of the current capability (sourcing capability) of the output stage 21. In a layout, resistors R1 and R2 of the current detecting circuit 10 are paired with each other. A DC ammeter 11 to measure a current output from the current detecting circuit 10 is connected to the current detecting circuit 10. The structure of the fourth preferred embodiment is the same in other respects as that of the first preferred embodiment, so that it will not be described here.

A method of adjusting the current capability of the driving circuit 2 (method of testing a semiconductor device driving circuit) is described next. Referring to FIG. 4, the driving circuit 2 and the input circuit 3 perform the same operations as those of the first preferred embodiment. A control signal to be input to the gate of the output stage 101 of the current detecting circuit 10 corresponds to a control signal to be input to the gate of the output stage 21 of the driving circuit 2. To be specific, the output stage 101 is driven by a voltage common to that for the output stage 21.

First, a short-circuit current is caused to flow in the output stage 101 of the current detecting circuit 10. The short-circuit current is diverted through the resistors R1 and R2, and current capability output from the current detecting circuit 10 is measured with the DC ammeter 11.

Next, a difference x[%] between the measured current capability of the output stage 101 and desirable characteristics is checked.

Then, the current capability of the output stage 21 is adjusted by trimming the aforementioned difference x[%]. To be specific, the current capability of the output stage 21 is adjusted based on the measured current capability of the output stage 101 and a design value of the current capability of the output stage 101. Current capability output from the driving circuit 2 is adjusted by adjusting the current capability of the output stage 21.

As described above, in the fourth preferred embodiment, the current capability of the driving circuit 2 is adjusted based on the current capability of the output stage 101 of the current detecting circuit 10. This allows adjustment such that the current capability of the driving circuit 2 becomes desirable characteristics.

In the fourth preferred embodiment, a common power source is used for the current detecting circuit 10 and the driving circuit 2. Meanwhile, respective power sources may be prepared for the current detecting circuit 10 and the driving circuit 2, and only the current detecting circuit 10 may be driven during the test.

### Fifth Preferred Embodiment

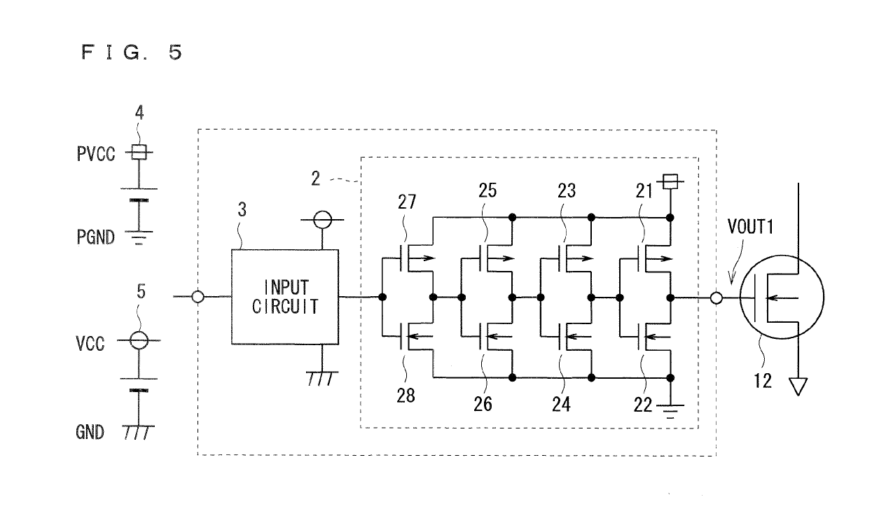

FIG. 5 shows an example of the structure of a semiconductor device driving circuit according to a fifth preferred embodiment of the present invention.

As shown in FIG. 5, a target to be driven by the semiconductor device driving circuit of the fifth preferred embodiment is an SiC device 12. The structure and the operation of the fifth preferred embodiment are the same in other respects as those of the first preferred embodiment, so that they will not be described here.

Even if the SiC device 12 to be driven with a higher voltage and a higher current is a target to be driven by the semiconductor device driving circuit, the fifth preferred embodiment still realizes adjustment such that the current capability of the driving circuit 2 becomes desirable characteristics.

The preferred embodiments of the present invention can be combined freely, and each of the preferred embodiments can be modified or omitted where appropriate without departing from the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device driving circuit, comprising:
a driving circuit that drives a semiconductor device;
an input circuit that gives a control signal to said driving circuit;
a driving power source that drives MOSFET output stages of said driving circuit; and
a control power source provided independently of said driving power source, the control power source driving said input circuit,
wherein only the driving voltage of said driving power source is reduced during a test and the current capability of said driving circuit is adjusted based on the current capabilities of said MOSFET output stages in a pentode region.

2. A method of testing the semiconductor device driving circuit as recited in claim 1, comprising the steps of:
(a) examining a correlation in advance between current capability determined when said driving voltage of said driving power source is low and that determined when said driving voltage is a general driving voltage;
(b) measuring current capability during said test determined when said driving voltage of said driving power source is low; and
(c) based on said current capability measured in said step (b), adjusting the current capability of said driving circuit determined when said driving voltage is a general driving voltage by taking said correlation examined in said step (a) into consideration.

3. The semiconductor device driving circuit according to claim 1, further comprising test MOSFET output stages respectively corresponding to any ones of said MOSFET output stages, and a test circuit driven by said driving power source,
wherein the current capability of said driving circuit is adjusted based on the current capability of said test MOSFET output stages.

4. A method of testing the semiconductor device driving circuit as recited in claim 3, comprising the steps of
(a) measuring the current capability of said test MOSFET output stage, and
(b) adjusting the current capability of said driving circuit based on a difference between said current capability measured in said step (a) and a design value of the current capability of said test MOSFET output stages.

5. The semiconductor device driving circuit according to claim 1, further comprising a first transistor corresponding to an N-channel MOSFET output stage of said MOSFET output stages, and a first current detecting circuit driven by said driving power source, wherein the current capability of said driving circuit is adjusted based on the current capability of said first transistor.

6. A method of testing the semiconductor device driving circuit as recited in claim 5, comprising the steps of
(a) measuring the current capability of said first transistor, and
(b) adjusting the current capability of said driving circuit based on a difference between said current capability measured in said step (a) and a design value of the current capability of said first transistor.

7. The semiconductor device driving circuit according to claim 1, further comprising a second transistor corresponding to a P-channel MOSFET output stage of said MOSFET output stages, and a second current detecting circuit driven by said driving power source,
wherein the current capability of said driving circuit is adjusted based on the current capability of said second transistor.

8. A method of testing the semiconductor device driving circuit as recited in claim 7, comprising the steps of
(a) measuring the current capability of said second transistor, and
(b) adjusting the current capability of said driving circuit based on a difference between said current capability measured in said step (a) and a design value of the current capability of said second transistor.

9. The semiconductor device driving circuit according to claim 1, wherein said semiconductor device is an SiC device.
